(19) United States
(12) Patent Application Publication
(10) Pub. No.: US 2019/0103760 A1
(43) Pub. Date: Apr. 4, 2019

(54) POWER SUPPLY SYSTEM

(71) Applicants: AUTONETWORKS TECHNOLOGIES, LTD., Yokkaichi (JP); SUMITOMO WIRING SYSTEMS, LTD., Yokkaichi (JP); SUMITOMO ELECTRIC INDUSTRIES, LTD., Osaka (JP)

(72) Inventor: Hisanori KAMBARA, Yokkaichi (JP)

(73) Assignees: AUTONETWORKS TECHNOLOGIES, LTD., Yokkaichi (JP); SUMITOMO WIRING SYSTEMS, LTD., Yokkaichi (JP); SUMITOMO ELECTRIC INDUSTRIES, LTD., Osaka (JP)

(21) Appl. No.: 16/142,531

(22) Filed: Sep. 26, 2018

(30) Foreign Application Priority Data
Oct. 3, 2017 (JP) 2017-193392

(51) Int. Cl. H02J 9/06; H02J 7/00; G01R 31/40

(52) U.S. Cl. CPC H02J 9/061; G01R 31/40; H02J 7/0068

(57) ABSTRACT

A power supply system includes a high-potential side output end and a low-potential side output end that output the power; an input end to which a positive voltage is applied from a DC power source; a power storage element including a positive terminal connected to the high-potential side output end and a negative terminal connected to the low-potential side output end; a diode including a cathode and an anode, the anode being connected to the input end; a power source line connected between the cathode and the positive terminal; and a switch, connected to the diode in parallel, that turns on when a current value of current flowing in the power source line from the cathode toward the positive terminal is greater than or equal to a positive threshold, and turns off when the current value is less than the threshold.

This application claims priority from JP 2017-193392 filed Oct. 3, 2017, the entire disclosure of which is incorporated herein by reference.

### BACKGROUND

This disclosure relates to a technique for supplying power to a load, and particularly relates to a power supply system that functions as a backup power source or a sub-power source for a DC power source.

JP-2008-29160A discloses a technique for supplying power to a load from a main power source through a voltage regulator, or from a backup power source through reverse current prevention means. Here, the backup power source is charged from the main power source through the voltage regulator. The voltage regulator is controlled on the basis of a comparison between the voltage of the backup power source and the voltage of the main power source, so that reverse current does not flow from the backup power source to the main power source.

### SUMMARY

However, with the configuration disclosed in JP-2008-29160A, reverse current is particularly likely to flow when the power capacitance rises. A high amount of reverse current will therefore flow when a sudden drop in voltage occurs due to a malfunction in the main power source, typified by a ground fault. This increases the likelihood that power cannot be supplied from the backup power source to the load at the appropriate timing.

An exemplary aspect of the disclosure provides a backup power source or a sub-power source that suppresses delay in the timing at which power is supplied to a load.

A power supply system supplies power to a load. The power supply system includes: a high-potential side output end and a low-potential side output end that output the power; an input end to which a positive voltage is applied from a DC power source; a power storage element including a positive terminal connected to the high-potential side output end and a negative terminal connected to the low-potential side output end; a diode including a cathode and an anode, the anode being connected to the input end; a power source line connected between the cathode and the positive terminal; and a switch, connected to the diode in parallel, that turns on when a current value of current flowing in the power source line from the cathode toward the positive terminal is greater than or equal to a positive threshold, and turns off when the current value is less than the threshold.

The power supply system functions as a backup power source or a sub-power source that suppresses delay in the timing of the supply of power to a load.

### BRIEF DESCRIPTION OF THE DRAWINGS

FIG. 1 is a block diagram illustrating the configuration of a power supply system according to an embodiment.

FIG. 2 is a timing chart illustrating a relationship between current, switch operations, and a load power source.

FIG. 3 is a flowchart illustrating switch opening/closing operations.

FIG. 4 is a flowchart illustrating switch opening/closing operations.

### DETAILED DESCRIPTION OF EMBODIMENTS

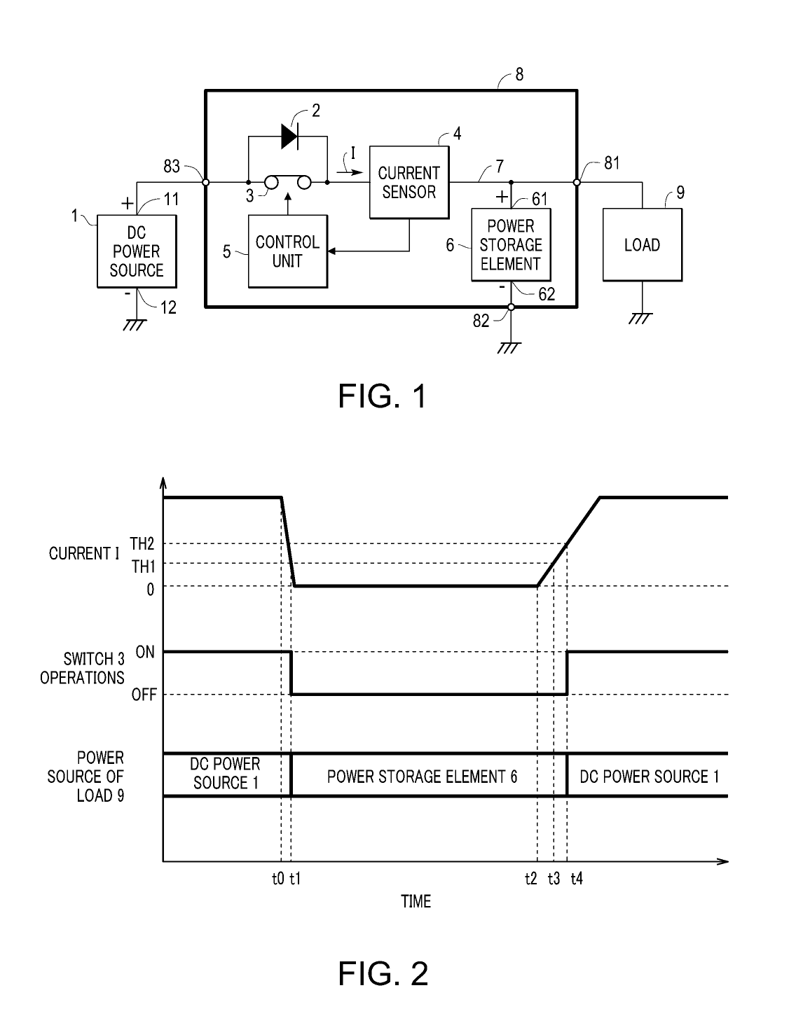

FIG. 1 is a block diagram illustrating the configuration of a power supply system 8 according to an embodiment. FIG. 1 also illustrates a connection relationship between the power supply system 8 and peripheral elements thereof.

The power supply system 8 includes a high-potential side output end 81 and a low-potential side output end 82, and these supply power to a load 9. Specifically, the high-potential side output end 81 is connected to one end of the load 9, and the low-potential side output end 82 is connected to the other end of the load 9. FIG. 1 illustrates an example in which both the other end of the load 9 and the low-potential side output end 82 are grounded.

The power supply system 8 further includes an input end 83. A positive voltage is applied to the input end 83 from a DC power source 1. FIG. 1 illustrates a case where a positive terminal 11 of the DC power source 1 is connected to the input end 83, and a negative terminal 12 of the DC power source 1 is grounded.

Assuming the power supply system 8 is installed in a vehicle, an alternator, a converter, or a lead storage battery can be given as an example of the DC power source 1. The load 9 is a load that desirably can be assured of operation even if the DC power source 1 malfunctions, such as an actuator, a sensor, or the like for steering or braking, for example.

The power supply system 8 further includes a diode 2, a switch 3, a power storage element 6, and a power source line 7. The power storage element 6 includes a positive terminal 61 and a negative terminal 62. The positive terminal 61 is connected to the high-potential side output end 81. The negative terminal 62 is connected to the low-potential side output end 82.

The power storage element 6 is capable of charging and discharging power, and is, for example, a lithium-ion battery, an electric double-layer capacitor, or the like.

The power source line 7 is connected between the cathode of the diode 2 and the positive terminal 61. The anode of the diode 2 is connected to the input end 83. The switch 3 is connected to the diode 2 in parallel. The switch 3 can be realized using a relay.

The switch 3 opens/closes depending on the value of current I flowing in the power source line 7 from the cathode toward the positive terminal 61. Controlling the opening/closing of the switch 3 will be described next using a timing chart and a flowchart.

FIG. 2 is a timing chart illustrating a relationship between the current I, operations of the switch 3, and a power source of the load 9. FIG. 2 indicates whether the switch 3 is on or off by the “ON” and “OFF” levels. The period where the power source of the load 9 is denoted as “DC power source 1” indicates that power is supplied from the DC power source 1 to the load 9. The period where the power source of the load 9 is denoted as “power storage element 6” indicates that power is supplied from the power storage element 6 to the load 9.

The DC power source 1 is operating normally before time to, and supplies power to the load 9 through the switch 3, which is on, or furthermore through the diode 2. The value of the current I at this time is from 50 to 100 A, for example.

Time t0 is a time at which a malfunction, e.g., a voltage drop, arises in the DC power source 1. The value of the current I drops suddenly after time t0. Time t1(>t0) is the time at which the current I has dropped from a value greater than or equal to a threshold TH1 to a value less than the threshold TH1 (referred to as a “falling event” hereinafter). To rephrase, the malfunction in the DC power source 1 is detected through the falling event. The switch 3 turns off in response to the falling event. For the sake of simplicity, FIG. 2 ignores a delay time from after the falling event has occurred to when the switch 3 turns off (referred to as an “off delay time” hereinafter), and indicates the switch 3 as transitioning from on to off at time t1.

By setting the threshold TH1 to a positive value, the value of the current I will not become negative even if the malfunction in the DC power source 1 continues and the value of the current I falls This is because the diode 2 prevents the current I from flowing in reverse.

The switch 3 turns off before a reverse current situation arises, and the power storage element 6 then handles the supply of power to the load 9. Accordingly, the power supply system 8 functions as a backup power source or a sub-power source that suppresses delay in the timing of the supply of power.

Time t2(>t1) is a time at which the DC power source 1 is restored from the malfunction. The value of the current I rises after time t2. Time t4(>t2) is the time at which the current I has risen from a value less than a threshold TH2 to a value greater than or equal to the threshold TH2 (referred to as a “rising event” hereinafter). To rephrase, the DC power source 1 being restored from the malfunction is detected through the rising event. The switch 3 turns on in response to the rising event. For the sake of simplicity, FIG. 2 ignores a delay time from after the rising event has occurred to when the switch 3 turns on (referred to as an “on delay time” hereinafter), and indicates the switch 3 as transitioning from off to on at time t4. When the switch 3 turns on, power is supplied to the load 9 from the DC power source 1.

Even if the switch 3 is off, the current I can flow from the DC power source 1 to the load 9 through the diode 2. Thus the timing at which the switch 3 is to be turned on can be obtained by monitoring the current I.

FIG. 2 illustrates an example in which the threshold TH2 employed when the current value rises is higher than the threshold TH1 employed when the current value falls. In other words, two types of thresholds are set as thresholds at which the switch 3 turns on and off, namely a first threshold (the threshold TH1) employed when the value of the current I is dropping, and a second threshold (the threshold TH2) employed when the value of the current I is rising. FIG. 2 illustrates an example in which the second threshold is higher than the first threshold. Time t3 is the time at which the current I has risen from a value less than the threshold TH1 to a value greater than or equal to the threshold TH1, with the relationship t2<t3<t4 holding true. If the threshold TH2 and the threshold TH1 are equal, time t3 and time t4 match.

Setting the threshold TH2 higher than the threshold TH1 makes it possible to reduce the occurrence of chattering in the switch 3. When the switch 3 turns off through the falling event, there are cases where the potential at the cathode of the diode 2 drops below the potential at the anode and the current I increases slightly. If TH1 is equal to TH2, the slight increase in the current I will correspond to the above-described rising event, and the switch 3 will turn on as a result. This causes the occurrence of chattering in the switch 3.

The value of the current I can be detected using a current sensor 4 provided in the power source line 7. The current sensor 4 can be realized through a known configuration. For example, a shunt resistor that produces a drop in voltage transformed to a current value may be used. The current sensor 4 communicates that current value to a control unit 5.

The on/off operations of the switch 3 can be controlled by the control unit 5. The control unit 5 controls the on/off operations of the switch 3 on the basis of a result of comparing the value of the current I with the thresholds TH1 and TH2.

Thus the power supply system 8 can be considered to further include the current sensor 4 and the control unit 5.

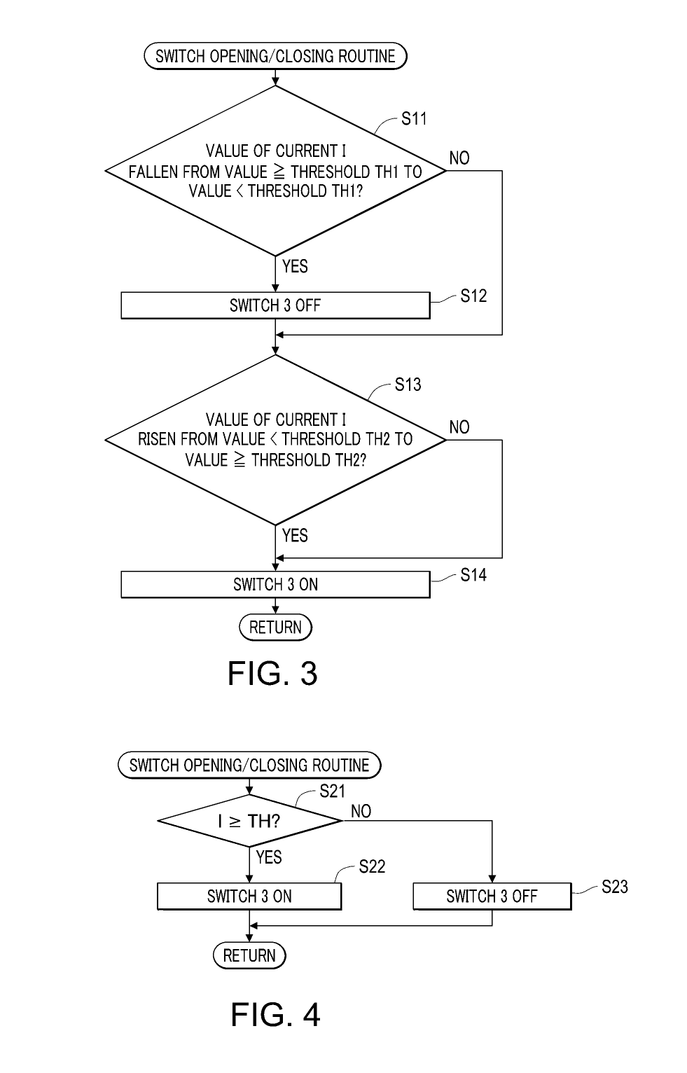

FIG. 3 is a flowchart illustrating opening/closing operations of the switch 3. This flowchart is illustrated as an example of a switch opening/closing routine, which is a subprogram of a main program (not illustrated). The subprogram is executed as an interrupt process for the main program, for example, and the processing returns to the main program when the subprogram ends.

The timing at which the value of the current I is obtained has been omitted from FIG. 3 for the sake of simplicity. However, the current value is obtained as appropriate, at a time required for the processing of the switch opening/closing routine. The switch opening/closing routine is executed repeatedly during a period shorter than a period required for the interval for controlling the on/off operations of the switch 3.

The switch opening/closing routine is executed by the control unit 5, for example. Step S11 is executed first upon the switch opening/closing routine being started. In step S11, it is determined whether or not the falling event has occurred. Specifically, it is determined whether the value of the current I has fallen from a value greater than or equal to the threshold TH1 to a value less than the threshold TH1. In terms of FIG. 2, a negative determination (“No” in FIG. 3; the same applies hereinafter) is made before time t1, and the process then moves to step S13.

In step S13, it is determined whether or not the rising event has occurred. Specifically, it is determined whether the value of the current I has risen from a value less than the threshold TH2 to a value greater than or equal to the threshold TH2. In terms of FIG. 2, a negative determination is made before time t1, and the switch opening/closing routine ends (the processing returns to the main program).

The switch 3 is on before time t1, and because the switch opening/closing routine did not control the operations of the switch 3, the switch 3 remains on.

Then, if the switch opening/closing routine is executed after time t1, a positive determination (“Yes” in FIG. 3; the same applies hereinafter) is made in step S11, and the process moves to step S12. Control for turning the switch 3 off is executed in step S12. The time following the occurrence of the falling event and leading up to the execution of step S12 is included in the off delay time.

After step S12 is executed, the process moves to step S13. Up until time t4, a negative determination is made in step S13, and the switch opening/closing routine ends with the switch 3 remaining off.

Then, if the switch opening/closing routine is executed after time t4, a negative determination is made in step S11, and the process moves to step S13. A positive determination is made in step S13, and the process moves to step S14. Control for turning the switch 3 on is executed in step S14. The time following the occurrence of the rising event and leading up to the execution of step S14 is included in the on delay time. The switch opening/closing routine ends after step S14 is executed.

From time t4 on, a negative determination is made in both steps S11 and S13, and the switch opening/closing routine ends with the switch 3 remaining on.

### First Variation

When the switch 3 is turned off, all of the current I flows to the diode 2. It is thus desirable that both the thresholds TH1 and TH2 be set to currents lower than the permissible current of the diode 2. The thresholds TH1 and TH2 are set to from 10 to 20 A, for example.

### Second Variation

In the flowchart illustrated in FIG. 3, the combination of steps S11 and S12 and the combination of steps S13 and S14 may have their order reversed.

### Third Variation

If it is not necessary to suppress chattering in the switch 3, the thresholds TH1 and TH2 need not be set to different values. FIG. 4 is a flowchart illustrating opening/closing operations of the switch 3, as the switch opening/closing routine, in a situation where both the thresholds TH1 and TH2 are set to the same value TH.

In step S21, it is determined whether the value of the current I is greater than or equal to a threshold TH. If a positive determination is made in step S21, the switch 3 is turned on in step S22. If a negative determination is made in step S21, the switch 3 is turned off in step S23. In terms of FIG. 2, time t3 and time t4 match, and thus it is clear that the same operations as those described in the embodiment above are achieved by executing steps S22, S23, and S24.

Thus it can be said that the switch 3 is turned on when the value of the current I is greater than or equal to the positive threshold TH2, and is turned off when the value of the current I is less than the threshold TH1. TH1=TH2 corresponds to the third variation, whereas TH2>TH1 corresponds to the embodiment. However, as described above, the threshold TH1 is a value employed when the current value decreases, whereas the threshold TH2 is a value employed when the current value increases.

The configurations described in the above embodiment and variations can be combined as appropriate as long as the configurations do not conflict with each other.

While the disclosure has been described in detail above, the foregoing descriptions are in all ways exemplary, and the disclosure is not intended to be limited thereto. It is to be understood that countless variations not described here can be conceived of without departing from the scope of the disclosure.

What is claimed is:

1. A power supply system that supplies power to a load, the system comprising:
a high-potential side output end and a low-potential side output end that output the power;
an input end to which a positive voltage is applied from a DC power source;
a power storage element including a positive terminal connected to the high-potential side output end and a negative terminal connected to the low-potential side output end;
a diode including a cathode and an anode, the anode being connected to the input end;
a power source line connected between the cathode and the positive terminal; and
a switch, connected to the diode in parallel, that turns on when a current value of current flowing in the power source line from the cathode toward the positive terminal is greater than or equal to a positive threshold, and turns off when the current value is less than the threshold.

2. The power supply system according to claim 1, wherein two types of the threshold are set, the two types being a first threshold employed when the current value is decreasing and a second threshold employed when the current value is increasing; and
the second threshold is higher than the first threshold.

3. The power supply system according to claim 1, wherein the threshold is set to be less than or equal to a permissible current of the diode.

4. The power supply system according to claim 1, further comprising:
a current sensor that detects the current value; and
a control unit that controls on/off operations of the switch on the basis of a result of comparing the current value to the threshold.
